(19) United States
(12) Patent Application Publication
(10) Pub. No.: US 2015/0162201 A1
(43) Pub. Date: Jun. 11, 2015

(54) SEMICONDUCTOR DEVICES AND METHODS OF MANUFACTURING THE SAME

(71) Applicant: Samsung Electronics Co., Ltd., Suwon-si (KR)

(72) Inventors: In-Hee Lee, Suwon-si (KR); Min-Woo Song, Seongnam-si (KR); Seok-Jun Won, Seoul (KR); Hyung-Suk Jung, Suwon-si (KR)

(21) Appl. No.: 14/477,273

(22) Filed: Sep. 4, 2014

(30) Foreign Application Priority Data
Dec. 11, 2013 (KR) 10-2013-0153863

(51) Int. Cl. H01L 21/28; H01L 21/02; H01L 29/66; H01L 29/40

(52) U.S. Cl. CPC H01L 21/28247; H01L 29/40; H01L 21/0228; H01L 29/66545

(57) ABSTRACT

In a method of manufacturing a semiconductor device, a dummy gate structure including a dummy gate electrode and a gate mask sequentially stacked on a substrate is formed. A spacer is formed on a sidewall of the dummy gate structure. The gate mask is formed to expose the dummy gate electrode and to form a recess on the spacer. A capping layer pattern is formed to fill the recess in the spacer. The exposed dummy gate electrode is replaced with a gate electrode.

### CROSS-REFERENCE TO RELATED APPLICATION

This application claims priority under 35 USC §119 to Korean Patent Application No. 10-2013-0153863, filed on Dec. 11, 2013 in the Korean Intellectual Property Office (KIPO), the contents of which are herein incorporated by reference in their entirety.

### BACKGROUND

1. Field

Example embodiments relate to semiconductor devices and methods of manufacturing the same. More particularly, example embodiments relate to semiconductor devices including gate structures and methods of manufacturing the same.

2. Description of the Related Art

When a gate structure is formed by a gate last process, after forming a dummy gate pattern using a gate mask, a spacer may be formed on sidewalls of the dummy gate pattern and the gate mask. When the gate mask is etched to expose a top surface of the dummy gate pattern, an upper portion of the spacer may be etched to form a dent. When the dummy gate pattern is removed to form a gate electrode and a contact plug is formed adjacent to the gate electrode, the gate electrode and the contact plug may touch each other to generate an electrical short.

### SUMMARY

Example embodiments provide a semiconductor device including a gate structure having good characteristics.

Example embodiments provide a method of manufacturing a semiconductor device including a gate structure having good characteristics.

According to example embodiments, there is provided a method of manufacturing a semiconductor device. In the method, a dummy gate structure including a dummy gate electrode and a gate mask sequentially stacked on a substrate is formed. A spacer is formed on a sidewall of the dummy gate structure. The gate mask is formed to expose the dummy gate electrode and to form a recess on the spacer. A capping layer pattern is formed to fill the recess in the spacer. The exposed dummy gate electrode is replaced with a gate electrode.

In example embodiments, the capping layer pattern may be formed to include a material having a high etching selectivity with respect to the dummy gate electrode.

In example embodiments, the dummy gate electrode may be formed to include polysilicon, and the capping layer pattern may be formed to include a nitride.

In example embodiments, the capping layer pattern may be formed to include silicon nitride, silicon oxynitride and/or silicon carbonitride.

In example embodiments, the gate mask and the spacer may be formed to include a nitride.

In example embodiments, a first insulating interlayer may be formed to cover the dummy gate structure and the spacer on the substrate. An upper portion of the first insulating interlayer may be planarized until a top surface of the gate mask is exposed.

In example embodiments, when the gate mask is removed, the exposed gate mask may be dry etched to form a first opening exposing a top surface of the dummy gate electrode. The first opening may be in fluid communication with the recess.

In example embodiments, when capping layer pattern is formed, a capping layer may be formed on the exposed top surface of the dummy gate electrode, the spacer and the first insulating interlayer. The capping layer may be etched by an etch back process to form the capping layer pattern.

In example embodiments, when the capping layer is formed, an atomic layer deposition (ALD) process may be performed at a temperature of about 200 to about 600° C.

In example embodiments, after forming the capping layer pattern, an upper portion of the first insulating interlayer may be planarized so that the first insulating interlayer may have a top surface substantially coplanar with the top surface of the dummy gate electrode,

In example embodiments, when the exposed dummy gate electrode is replaced with the gate electrode, the exposed dummy gate electrode may be removed to form a second opening. The gate electrode may be formed to fill the second opening.

In example embodiments, when the dummy gate structure is formed, a gate insulation layer, a dummy gate electrode layer and a gate mask layer may be sequentially formed on the substrate. The gate mask layer may be patterned to form the gate mask. The dummy gate electrode layer and the gate insulation layer may be patterned using the gate mask as an etching mask to form a gate insulation layer pattern and the dummy gate electrode sequentially stacked on the substrate.

In example embodiments, a high-k dielectric layer pattern may be formed on a top surface of the gate insulation layer pattern, which may be exposed by the second opening, and a sidewall of the second opening. The gate electrode may be formed on the high-k dielectric layer pattern to fill a remaining portion of the second opening.

According to example embodiments, there is provided a semiconductor device. The semiconductor device includes a gate structure, a spacer and a capping layer pattern. The gate structure includes a gate insulation layer pattern on a substrate, a high-k dielectric layer pattern covering a bottom and a sidewall of the gate electrode on the gate insulation layer pattern, and a gate electrode on the gate insulation layer pattern. The spacer, which has a concave top surface and includes a nitride, is on a sidewall of the gate structure. The capping layer pattern, which has a convex bottom corresponding to the concave top surface of the spacer, and has a top surface substantially coplanar with a top surface of the gate structure, is on the spacer.

In example embodiments, the spacer may include silicon nitride, and the capping layer pattern may include silicon oxynitride or silicon carbonitride.

According to example embodiments, when etching a gate mask on a dummy gate electrode, a capping layer pattern including a material having a high etching selectivity with respect to the dummy gate electrode may be formed to fill a recess on a spacer adjacent to the gate mask, which may be formed in the etching of the gate mask. Thus, the capping layer pattern may not be removed when etching the dummy gate electrode, and a gate electrode replacing the dummy gate electrode later may be sufficiently or fully covered by the spacer and the capping layer pattern, so that an electrical short between the gate electrode and a contact plug adjacent thereto may be prevented or the likelihood of an electrical short occurring reduced.

### BRIEF DESCRIPTION OF THE DRAWINGS

Example embodiments will be more clearly understood from the following detailed description taken in conjunction with the accompanying drawings. FIGS. 1 to 13 represent non-limiting, example embodiments as described herein.

FIGS. 1 to 13 are cross-sectional views illustrating stages of a method of manufacturing a semiconductor device in accordance with example embodiments.

### DESCRIPTION OF EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and device structures thereon, as would be illustrated by a plan view of the device/structure.

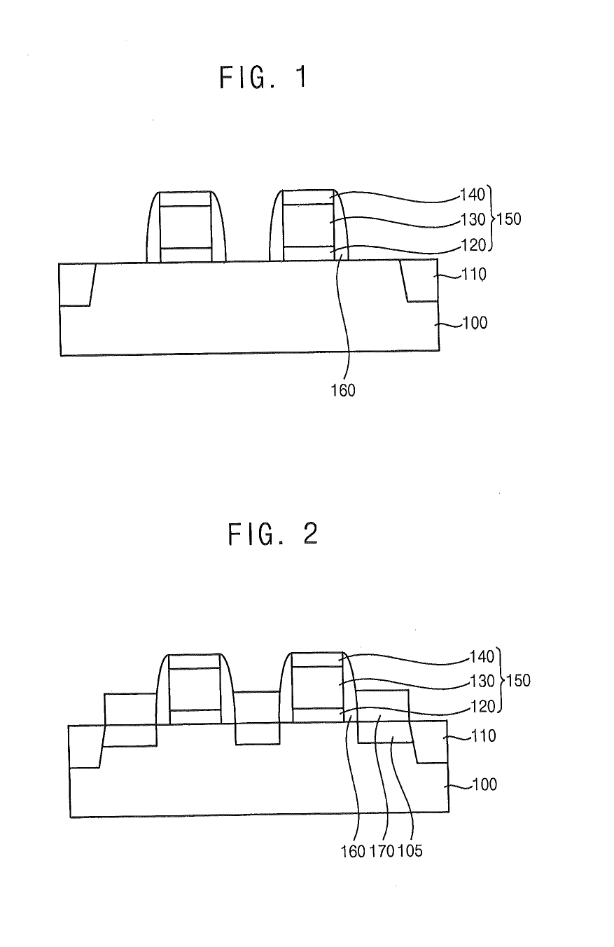

FIGS. 1 to 13 are cross-sectional views illustrating stages of a method of manufacturing a semiconductor device in accordance with example embodiments.

Referring to FIG. 1, an isolation layer 110 may be formed on a substrate 100, and a dummy gate structure 150 may be formed on the substrate 100 and the isolation layer 110.

The substrate 100 may be a silicon substrate, a germanium substrate, a silicon-germanium substrate, a silicon-on-insulator (SOT) substrate, a germanium-on-insulator (GOI) substrate, etc. The substrate 100 may be divided into a field region on which the isolation layer 110 is formed and an active region on which no isolation layer is formed. In example embodiments, the isolation layer 110 may be formed by a shallow trench isolation (STI) process, and may be formed to include an oxide, e.g., silicon oxide.

The dummy gate structure 150 may be formed by sequentially stacking a gate insulation layer and a dummy gate electrode layer and a gate mask layer, patterning the gate mask layer by a photolithography process using a photoresist pattern (not shown) to form a gate mask 140, and patterning the dummy gate electrode layer and the gate insulation layer using the gate mask 140 as an etching mask. Thus, the dummy gate structure 150 may be formed to include a gate insulation layer pattern 120, a dummy gate electrode 130 and a gate mask 140 sequentially stacked on the substrate 100 and the isolation layer 110.

The gate insulation layer may be formed to include an oxide, e.g., silicon oxide, the dummy gate electrode layer may be formed to include, e.g., polysilicon, and the gate mask layer may be formed to include a nitride, e.g., silicon nitride. The gate insulation layer may be formed by a chemical vapor deposition (CVD) process, an atomic layer deposition (ALD) process, etc. Alternatively, the gate insulation layer may be formed by a thermal oxidation process on an upper portion of the substrate 100. The dummy gate electrode layer and the gate mask layer may be also formed by a CVD process, an ALD process, etc.

The dummy gate structure 150 may be formed only on the active region of the substrate 100. Alternatively, the dummy gate structure 150 may be also formed on the isolation layer 110 so as to be formed on both of the active region and the field region of the substrate 100. In example embodiments, the dummy gate structure 150 may be formed to extend in a first direction on the substrate 100 and the isolation layer 110, and a plurality of dummy gate structures 150 may be formed in a second direction substantially perpendicular to the first direction.

A spacer layer covering the dummy gate structure 150 may be formed on the substrate 100 and the isolation layer 110, and etched by an anisotropic etching process to form a spacer 160 on a sidewall of the dummy gate structure 150. For example, the spacer layer may be formed to include a nitride, e.g., silicon nitride. The spacer layer may be formed by an ALD process, a CVD process, etc.

Referring to FIG. 2, an impurity region 105 may be formed at an upper portion of the active region of the substrate 100 adjacent to the dummy gate structure 150, and an elevated source drain (ESD) layer 170 may be formed on the impurity region 105.

Particularly, the active region of the substrate 100 may be partially removed using the dummy gate structure 150 and the spacer 160 as an etching mask to form a trench (not shown) at an upper portion of the active region, and the impurity region 105 may be formed to fill the trench.

In example embodiments, a first selective epitaxial growth (SEG) process may be performed using a top surface of the substrate 100 exposed by the trench as a seed layer to form the impurity region 105. The first SEG process may be performed using, e.g., dichlorosilane (SiH₂Cl₂) gas, germane (GeH₄) gas, etc., as a source gas, and thus a single crystalline silicon-germanium layer may be formed. In example embodiments, p-type impurity source gas, e.g., diborane (B₂H₆) gas may be also used to form a single crystalline silicon-germanium layer doped with p-type impurities. In this case, the impurity region 105 may serve as a source/drain region of a positive-channel metal oxide semiconductor (PMOS) transistor.

Alternatively, the first SEG process may be performed using disilane (Si₂H₆) gas and monomethylsilane (SiH₃CH₃) gas as a source gas to form a single crystalline silicon carbide layer. In example embodiments, n-type impurity source gas, e.g., phosphine (PH₃) gas may be also used to form a single crystalline silicon carbide layer doped with n-type impurities. In this case, the impurity region 105 may serve as a source/drain region of a negative-channel metal oxide semiconductor (NMOS) transistor.

A second SEG process may be performed to form the ESD layer 170 on the impurity region 105. The second SEG process may be performed using the impurity region 105 as a seed layer. The second SEG process may be performed using, e.g., dichlorosilane (SiH₂Cl₂) gas and diborane (13₂H₆) gas as a source gas, and thus a single crystalline silicon layer doped with p-type impurities may be formed. Alternatively, the second SEG process may be performed using, e.g., dichlorosilane (SiH₂Cl₂) gas and phosphine (PH₃) gas as a source gas, and thus a single crystalline silicon layer doped with n-type impurities may be formed.

In example embodiments, the first SEG process for forming the impurity region 105 and the second SEG process for forming the ESD layer 170 may be performed in-situ. That is, when the impurity region 105 may be formed, a silicon source gas, a germanium source gas and a p-type impurity source gas may be provided to perform an SEG process, and providing the germanium source gas may be stopped to form the ESD layer 170. Alternatively, when the impurity region 105 may be formed, a silicon source gas, a carbon source gas and an n-type impurity source gas may be provided to perform an SEG process, and providing the carbon source gas may be stopped to form the ESD layer 170.

A method of forming the impurity region 105 in which the trench is formed and the SEG processes are performed is described above, however, the impurity region 105 may be also formed by implanting impurities into an upper portion of the substrate 100 adjacent to the dummy gate structure 150. Additionally, the ESD layer 170 may not be formed. For the convenience of explanation, only the case in which the impurity region 105 is formed by the SEG processes and the ESD layer 170 is formed on the impurity region 105 will be illustrated hereinafter.

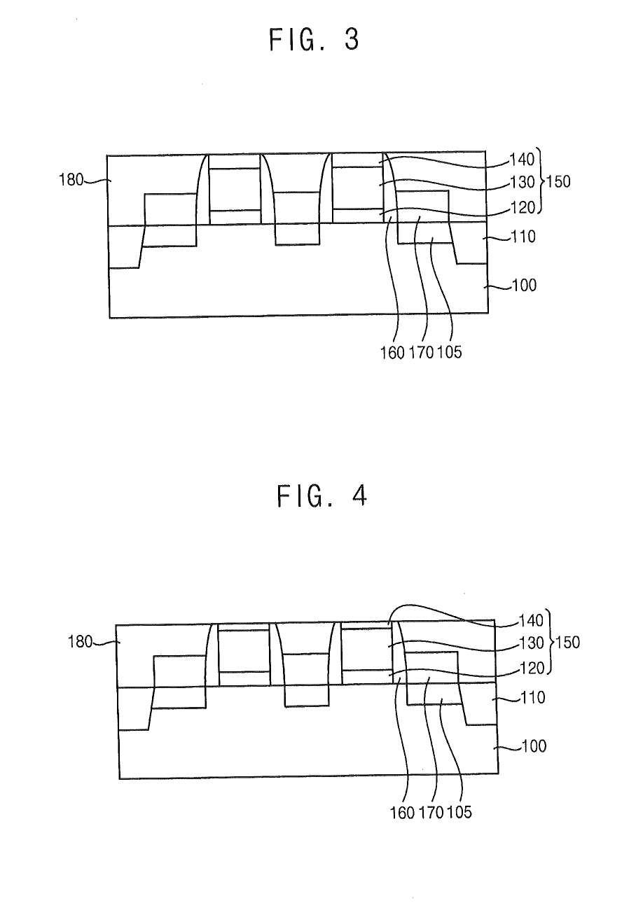

Referring to FIG. 3, a first insulating interlayer 180 covering the dummy gate structure 150, the spacer 160 and the ESD layer 170 may be formed on the substrate 100 and the isolation layer 110, and the first insulating interlayer 180 may be planarized until a top surface of the dummy gate structure 150 may be exposed. Before forming the first insulating interlayer 180, an etch stop layer (not shown) may be further formed to include, e.g., silicon nitride on the dummy gate structure 150, the spacer 160 and the ESD layer 170.

For example, the first insulating interlayer 180 may be formed to include silicon oxide. In example embodiments, the planarization process may be performed by a chemical mechanical polishing (CMP) process and/or an etch back process.

Referring to FIG. 4, the planarization process may be performed until an upper portion of the gate mask 140 may be exposed, and in this case, an upper portion of the spacer 160 may be also removed.

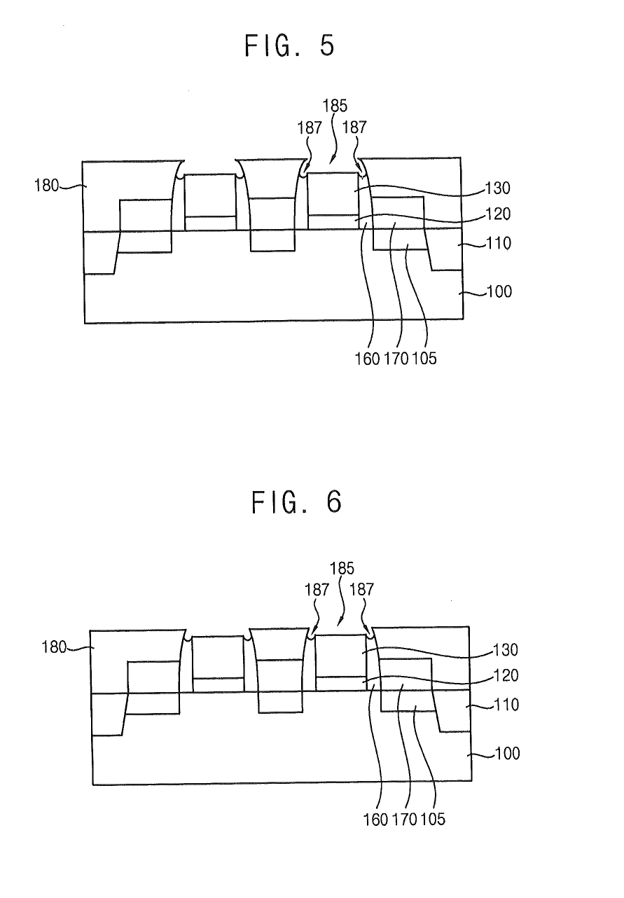

Referring to FIG. 5, the exposed gate mask 140 may be removed to form a first opening 185 exposing a top surface of the dummy gate electrode 130.

In example embodiments, the gate mask 140 may be removed by a dry etch process, and an upper portion of the spacer 160 adjacent to the gate mask 140 may be also removed. To sufficiently remove the gate mask 140, the gate mask 140 may be over-etched, and thus a recess 187 may be formed on the spacer 160 so that the spacer 160 may have a concave top surface.

Alternatively, the gate mask 140 may be removed by a wet etch process, and in this case also, the gate mask 140 may be over-etched to form the recess 187 on the spacer 160.

Referring to FIG. 6, when the planarization process is performed until an upper portion of the gate mask 140 may be removed so that an upper portion of the spacer 160 is also partially removed, the spacer 160 may be removed more during the removal of the gate mask 140 so that the recess 187 may be greater than that of FIG. 5.

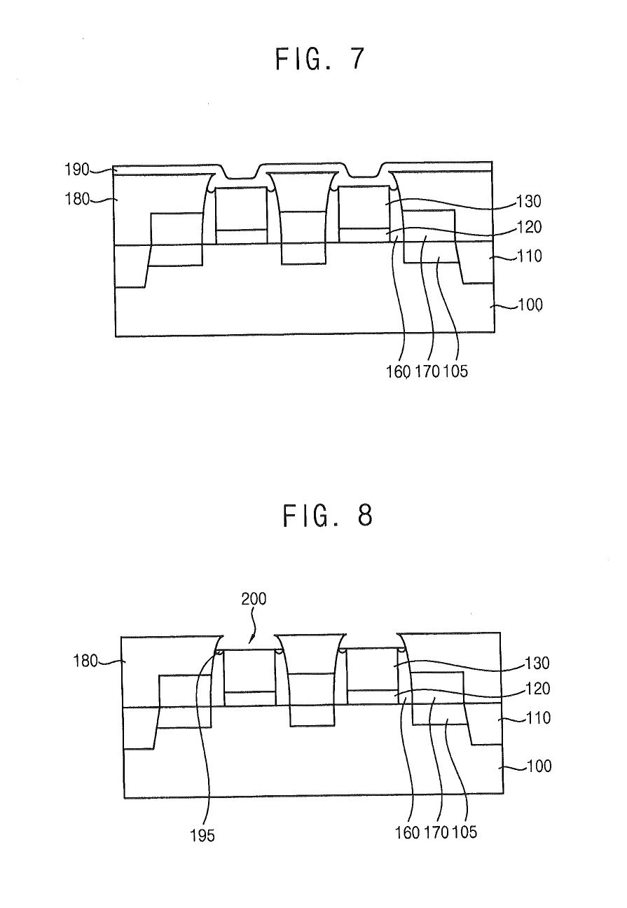

Referring to FIG. 7, a capping layer 190 may be formed on the exposed top surface of the dummy gate electrode 130, the spacer 160 and the first insulating interlayer 180 to sufficiently fill the recess 187. The first opening 185 may be sufficiently or fully filled with the capping layer 190, or partially filled with the capping layer 190.

In example embodiments, the capping layer 190 may be formed to include a material having a high etching selectivity with respect to the dummy gate electrode 130. When the dummy gate electrode 130 includes polysilicon, the capping layer 190 may be formed to include a nitride, e.g., silicon nitride, silicon oxynitride, silicon carbonitride, etc.

In example embodiments, the capping layer 190 may be formed by an ALD process at a temperature of about 200 to about 600° C., and may have a thickness of about 10 to about 200 Å.

Referring to FIG. 8, the capping layer 190 may be partially removed to form a capping layer pattern 195 on the spacer 160.

In example embodiments, portions of the capping layer 190 on the dummy gate electrode 130 and the first insulating interlayer 180 may be removed by an etch back process, and a portion of the capping layer 190 on the spacer 160 adjacent to the dummy gate electrode 130 may be also removed.

Thus, the capping layer pattern 195 may be formed to fill the recess 187 on the spacer 160. The recess 187 has a concave shape so that the capping layer pattern 195 may include a bottom surface having a convex shape corresponding thereto.

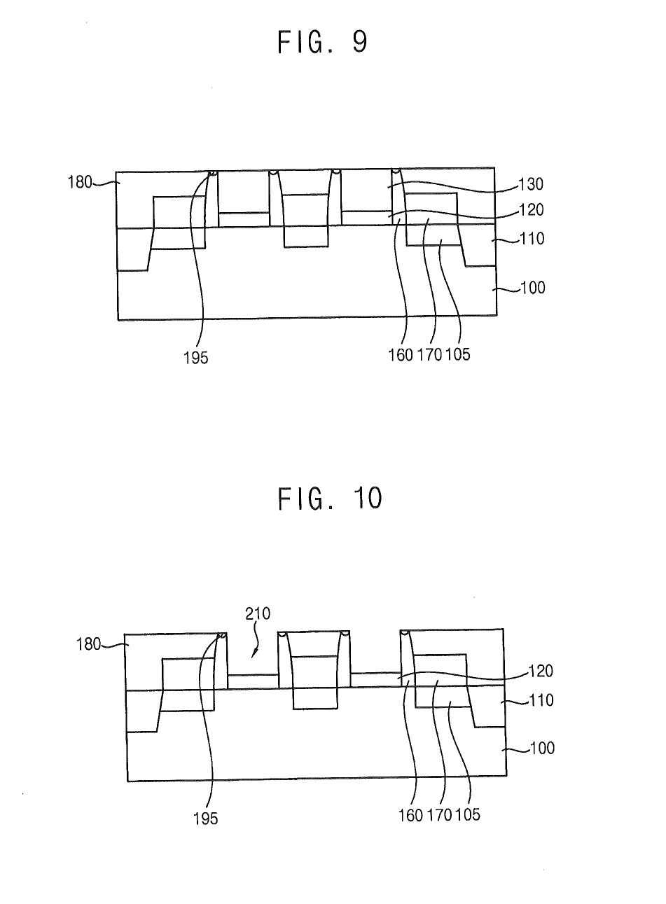

Referring to FIG. 9, the first insulating interlayer 180 may be planarized so as to have a top surface substantially coplanar with a top surface of the dummy gate electrode 130. In this case, an upper portion of the capping layer pattern 195 may be also planarized, so that the capping layer pattern 195 may have a flat top surface substantially coplanar with the top surface of the dummy gate electrode 130. In example embodiments, the planarization process may be performed using the top surface of the dummy gate electrode 130 as a polishing endpoint.

Referring to FIG. 10, the dummy gate electrode 130 may be removed to form a second opening 210 exposing a top surface of the gate insulation layer pattern 120. That is, the second opening 210 may be defined by the top surface of the gate insulation layer pattern 120 and an inner sidewall of the spacer 160.

In example embodiments, the dummy gate electrode 130 may be sufficiently or fully removed by performing a dry etch process and performing a wet etch process. The wet etch process may be performed using HF as an etching solution, and the spacer 160 and the capping layer pattern 195 on the spacer 160 may not be easily etched by the HF solution but may remain because the spacer 160 and the capping layer pattern 195 may include a nitride.

That is, the spacer 160 and the capping layer pattern 195 may be formed to include a material having a high etching selectivity with respect to the dummy gate electrode 130 so as not to be etched during removing the dummy gate electrode 130.

Referring to FIG. 11, a high-k dielectric layer may be formed on the exposed top surface of the gate insulation layer pattern 120, a sidewall of the second opening 210 and a top surface of the first insulating interlayer 180, and a gate electrode layer may be formed on the high-k dielectric layer to sufficiently or fully fill the second opening 210.

The high-k dielectric layer may be formed to include a metal oxide having a high dielectric constant, e.g., hafnium oxide, tantalum oxide, zirconium oxide, etc. The gate electrode layer may be formed to include a material having a low resistance, e.g., a metal, such as aluminum, copper, tantalum, etc., or a metal nitride thereof by an ALD process, a physical vapor deposition (PVD) process, etc. In an example embodiment, a heat treatment process, e.g., a rapid thermal annealing (RTA) process, a spike rapid thermal annealing (spike RTA) process, a flash rapid thermal annealing (flash RTA) process or a laser annealing process may be further performed. Alternatively, the gate electrode layer may be formed to include doped polysilicon.

The gate electrode layer and the high-k dielectric layer may be planarized until the top surface of the first insulating interlayer 180 may be exposed to form a high-k dielectric layer pattern 220 on the top surface of the gate insulation layer pattern 120 and the sidewall of the second opening 210, and a gate electrode layer filling a remaining portion of the second opening 210 on the high-k dielectric layer pattern 220. Thus, a bottom and a sidewall of the gate electrode 230 may be covered by the high-k dielectric layer pattern 220. In example embodiments, the planarization process may be performed by a CMP process and/or an etch back process.

By the above processes, a gate structure 240 including the gate insulation layer pattern 120, the high-k dielectric layer pattern 220 and the gate electrode 230 sequentially stacked may be formed on the substrate 100 and/or the isolation layer 110. The gate structure 240 and the impurity region 105 and the ESD layer 170 adjacent thereto may form a transistor, and the impurity region 105 and the ESD layer 170 may serve as a source/drain region of the transistor.

The spacer 160 and the capping layer pattern 195 may be formed on a sidewall of the gate structure 240, and the capping layer pattern 195 may be formed on the spacer 160 to cover an upper sidewall of the gate structure 240.

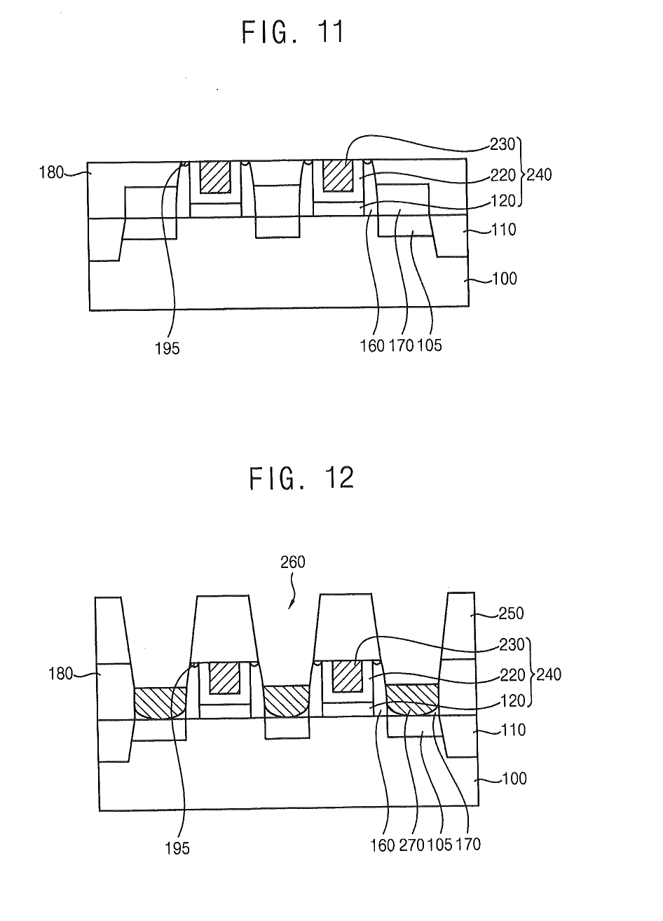

Referring to FIG. 12, a second insulating interlayer 250 may be formed on the first insulating interlayer 180 and the gate structure 240, the spacer 160 and the capping layer pattern 195, and a third opening 260 may be formed through the first and second insulating interlayers 180 and 250 to expose a top surface of the ESD layer 170.

The second insulating interlayer 250 may be formed to include an oxide, e.g., silicon oxide. The second insulating interlayer 250 may be formed to include a material substantially the same as or different from that of the first insulating interlayer 180.

The third opening 260 may be formed by forming a photoresist pattern (not shown) and performing a dry etch process using the photoresist pattern as an etching mask. In the dry etch process, an upper portion of the ESD layer 170 may be partially removed.

In example embodiments, the third opening 260 may be formed to be self-aligned with the spacer 160 and the capping layer pattern 195. The spacer 160 and the capping layer pattern 195 may include a material having a high etching selectivity with respect to the material of the first and second insulating interlayers 180 and 250, e.g., silicon nitride, so as not to be removed during the etching process for forming the third opening 260. Thus, the gate structure 240 sidewalls covered by the spacer 160 and the capping layer pattern 195 may not exposed by the etching process.

A metal silicide pattern 270 may be formed on the exposed top surface of the ESD layer 170.

Particularly, a metal layer may be formed on the exposed top surface of the ESD layer 170, a sidewall of the third opening 260 and a top surface of the second insulating interlayer 250 and thermally treated so that a silicidation process may be performed on the metal layer and the ESD layer 170. In an example embodiment, the heat treatment may be performed at a temperature of less than about 400° C.

Thus, a metal silicide layer may be formed on the ESD layer 170 and a portion of the metal layer that has not been reacted with the ESD layer 170 may be removed, so that the metal silicide pattern 270 may be formed on the ESD layer 170. In example embodiments, the metal layer may be formed to include nickel, cobalt, platinum, etc., and thus the metal silicide pattern 270 may be formed to include nickel silicide, cobalt silicide, platinum silicide, etc.

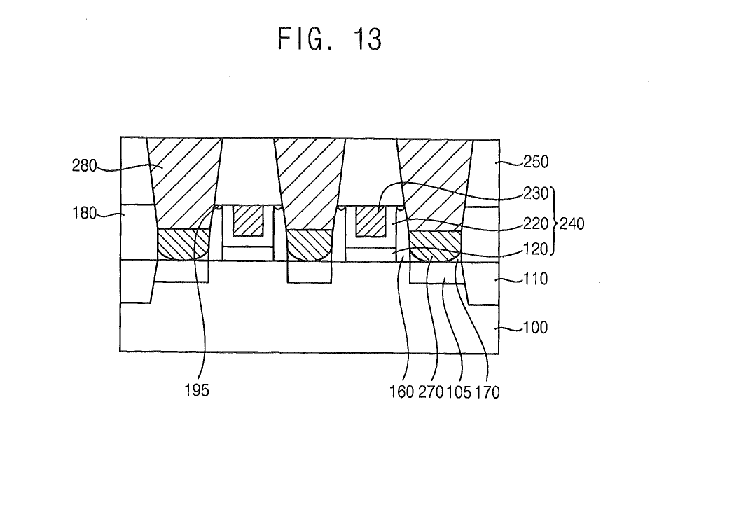

Referring to FIG. 13, a contact plug 280 may be formed to fill the third opening 260.

The contact plug 280 may be formed by forming a barrier layer (not shown) on a top surface of the metal silicide pattern 270, the sidewall of the third opening 260 and the top surface of the second insulating interlayer 250, forming a conductive layer on the barrier layer to sufficiently or fully fill a remaining portion of the third opening 260, and planarizing the conductive layer and the barrier layer until the top surface of the second insulating interlayer 250 may be exposed. In example embodiments, the barrier layer may be formed to include a metal and/or a metal nitride, and the conductive layer may be formed to include doped polysilicon, a metal, a metal nitride and/or a metal silicide.

By the above processes, the semiconductor device may be manufactured according to example embodiments.

As illustrated above, when forming the third opening 260, the spacer 160 and the capping layer pattern 195 covering sidewalls of the gate structure 240 may not removed, the contact plug 280 may not contact the gate structure 240. Thus, the semiconductor device may be manufactured not to have or reduce the risk of an electrical short therein.

The above semiconductor device may be applied to various types of memory devices including gate structures. For example, the semiconductor device may be applied to gate structures of logic devices, such as central processing units (CPUs), main processing units (MPUs), or application processors (APs), etc. Additionally, the semiconductor device may be applied to gate structures in a memory cell region or a peripheral circuit region of volatile memory devices, such as DRAM devices or SRAM devices, or non-volatile memory devices, such as flash memory devices, PRAM devices, MRAM devices, RRAM devices, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of manufacturing a semiconductor device, comprising:
forming a dummy gate structure comprising a dummy gate electrode and a gate mask sequentially stacked on a substrate;
forming a spacer on a sidewall of the dummy gate structure;
removing the gate mask to expose the dummy gate electrode and to form a recess on the spacer;
forming a capping layer pattern to fill the recess on the spacer; and
replacing the exposed dummy gate electrode with a gate electrode.

2. The method of claim 1, wherein the capping layer pattern is formed to comprise a material having a high etching selectivity with respect to the dummy gate electrode.

3. The method of claim 2, wherein the dummy gate electrode is formed to comprise polysilicon, and the capping layer pattern is formed to comprise a nitride.

4. The method of claim 3, wherein the capping layer pattern is formed to comprise silicon nitride, silicon oxynitride and/or silicon carbonitride.

5. The method of claim 1, wherein the gate mask and the spacer are formed to comprise a nitride.

6. The method of claim 1, further comprising:
forming a first insulating interlayer to cover the dummy gate structure and the spacer on the substrate; and
planarizing an upper portion of the first insulating interlayer until a top surface of the gate mask is exposed.

7. The method of claim 6, wherein removing the gate mask comprises dry etching the exposed gate mask to form a first opening exposing a top surface of the dummy gate electrode, the first opening being in fluid communication with the recess.

8. The method of claim 7, wherein forming the capping layer pattern comprises:
forming a capping layer on the exposed top surface of the dummy gate electrode, the spacer and the first insulating interlayer; and
etching the capping layer by an etch back process to form the capping layer pattern.

9. The method of claim 8, wherein forming the capping layer comprises performing an atomic layer deposition (ALD) process at a temperature of about 200 to about 600° C.

10. The method of claim 8, after forming the capping layer pattern, further comprising planarizing an upper portion of the first insulating interlayer so that the first insulating interlayer has a top surface substantially coplanar with the top surface of the dummy gate electrode.

11. The method of claim 1, wherein replacing the exposed dummy gate electrode with the gate electrode comprises:
removing the exposed dummy gate electrode to form a second opening; and
forming the gate electrode to fill the second opening.

12. The method of claim 11, wherein forming the dummy gate structure comprises:
sequentially forming a gate insulation layer, a dummy gate electrode layer and a gate mask layer on the substrate;
patterning the gate mask layer to form the gate mask; and
patterning the dummy gate electrode layer and the gate insulation layer using the gate mask as an etching mask to form a gate insulation layer pattern and the dummy gate electrode sequentially stacked on the substrate.

13. The method of claim 12, further comprising:
forming a high-k dielectric layer pattern on a top surface of the gate insulation layer pattern and a sidewall of the second opening, the top surface of the gate insulation layer pattern being exposed by the second opening; and
forming the gate electrode on the high-k dielectric layer pattern to fill a remaining portion of the second opening.

14. A semiconductor device, comprising:
a gate structure comprising:
a gate insulation layer pattern on a substrate;
a gate electrode on the gate insulation layer pattern; and
a high-k dielectric layer pattern on the gate insulation layer pattern, the high-k dielectric layer pattern covering a bottom and a sidewall of the gate electrode;
a spacer on a sidewall of the gate structure, the spacer having a concave top surface and comprising a nitride; and
a capping layer pattern on the spacer, the capping layer pattern having a convex bottom corresponding to the concave top surface of the spacer, and having a top surface substantially coplanar with a top surface of the gate structure.

15. The semiconductor device of claim 14, wherein the spacer comprises silicon nitride, and the capping layer pattern comprises silicon oxynitride or silicon carbonitride.

16. A method of manufacturing a semiconductor device, comprising:
forming a dummy gate structure comprising a dummy gate electrode on a substrate;
forming a gate mask on the dummy gate electrode;
forming spacers on sidewalls of the dummy gate structure and the gate mask;
removing the gate mask and portions of the spacers so as to expose an upper surface of the dummy gate electrode and sidewall portions of the dummy gate electrode; and
forming a capping layer pattern on the spacers and the sidewall portions of the dummy gate electrode.

17. The method of claim 16, further comprising:
removing the dummy gate electrode to form an opening; and
forming a gate structure in the opening;
wherein the capping layer pattern is disposed on sidewalls of the gate structure.

18. The method of claim 17, wherein the gate structure comprises a dielectric layer pattern and a gate electrode on the dielectric layer pattern; and
wherein the capping layer pattern is disposed on sidewalls of the dielectric layer pattern.

19. The method of claim 17, further comprising:
forming a contact plug such that the capping layer pattern is directly disposed on a sidewall of the contact plug.

20. The method of claim 17, wherein the capping layer pattern has a high etching selectivity with respect to the dummy gate electrode.
